(19) United States
(12) Patent Application Publication
(10) Pub. No.: US 2006/0267064 A1
(43) Pub. Date: Nov. 30, 2006

(54) Semiconductor memory device

(75) Inventors: Wolfgang Rosner, Ottobrunn (DE); Franz Hofmann, Munchen (DE); Michael Specht, Munchen (DE); Martin Stadele, Ottobrunn (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/139,977

(22) Filed: May 31, 2005

(51) Int. Cl. H01L 29/94

(52) U.S. Cl. 257/304

(57) ABSTRACT

The semiconductor memory device comprises a plurality of memory cells. Each memory cell comprises a respective transistor and a respective capacitor unit. The transistor comprises a transistor body of a first conductivity type, a drain area and a source area each having a second conductivity type, the drain area and source area are embedded in the transistor body on a first surface of the transistor body, and a gate structure having a gate dielectric layer and a gate electrode, the gate structure is arranged between the drain area and the source area. An isolation trench is arranged adjacent to said transistor body, having a dielectric layer and a conductive material, wherein the isolation trench is at least partially filled with the conductive material. The conductive material is isolated by said dielectric layer from the transistor body. The capacitor unit is formed by the transistor body representing a first electrode and the conductive material representing the second electrode.

### TECHNICAL FIELD OF THE INVENTION

The present invention relates to a semiconductor memory device.

### BACKGROUND OF THE INVENTION

Although the invention can in principle be applied to any desired semiconductor memory device, the invention and its underlying problem will hereinafter be explained with reference to random access memory devices.

A commonly known random access memory device comprises a plurality of memory cells each provided with one transistor and one capacitor, so-called one-transistor-one-capacitor-cells. A binary information is stored in the memory cell as a charge in the capacitor. A read out of the information is achieved by addressing the transistor via a bit line and a word line. A current flow of the charge from the capacitor through the transistor into the bit line is detected and interpreted via a reading decoder. For a reliable operation of the reading decoder a minimal charge is necessary thus demanding for a minimal capacitance of about 30 fF to 40 fF.

There is a demand to integrate a large amount of memory cells on an acceptably small area. Therefore, the lateral dimensions of the capacitor and the transistors need to be reduced.

The capacitance of a capacitor depends especially on the surface area of the electrodes of the capacitors. At present, the surface of the electrodes and thus the minimal capacitance is maintained by increasing the vertical dimensions or folding the electrodes for compensating the shrinking lateral dimensions. However, at present it is no more feasible to manufacture capacitors with further reduced lateral dimensions.

Further, as a separation of the source and drain area is shrinking along with the reduction of the lateral dimensions, a channel length becomes shorter. The shorter channel leads to higher leakage currents from drain to source. Therefore, the maintenance time of the charge in the capacitor is reduced. Thus, disadvantageously, a higher refresh rate of the charge becomes necessary.

S. Okhonin et. al. describe in IEEE, Electron Device Letters, Vol. 23, No. 2, page 85, February 2002 a memory cell consisting of a transistor. Information is stored as a charge injected into a transistor body of the respective transistor. The injected charge shifts a threshold value of the transistor. Thus a read-out of the information may be obtained by determining the threshold value of the transistor. The maintenance time for the injected charges is in the range of a few milliseconds. Compared to 250 ms of DRAM devices of present state of the art this maintenance time is unacceptably low. A reliable operation of such a memory cell would require a very high refresh rate of the injected charges.

### SUMMARY OF THE INVENTION

The present invention provides a semiconductor memory device with further reduced lateral dimensions and a sufficient maintenance time of information stored therein.

According to one embodiment of the present invention, the semiconductor memory device comprises a plurality of memory cells. Each memory cell comprises a respective transistor and a respective capacitor unit. The transistor comprises a transistor body of a first conductivity type, a drain area and a source area each having a second conductivity type, the drain area and source area are embedded in the transistor body on a first surface of the transistor body, and a gate structure having a gate dielectric layer and a gate electrode, the gate structure is arranged between said drain area and the source area. An isolation trench is arranged adjacent to the transistor body, having a dielectric layer and a conductive material, wherein the isolation trench is at least partially filled with the conductive material. The conductive material is isolated by said dielectric layer from the transistor body. The capacitor unit is formed by the transistor body representing a first electrode and the conductive material representing the second electrode.

In one aspect of the present invention, a charge stored in the semiconductor body shifts a threshold voltage from a first voltage to a second voltage. A read-out of the memory cell may, for example, be achieved by applying the first voltage to the gate and detecting the resistivity.

The maintenance time of the charges in the transistor body is increased by the capacitor unit. Additionally, a larger amount of charges may be stored in the transistor body thus further increasing the reliability of the read-out of the semiconductor memory device.

The transistor body and the isolation trenches need to be provided in any case. Thus a lateral space consumption of the capacitor unit is very low or may be even be considered to be zero.

According to one aspect of the invention, a first vertical level is defined between a bottom of the isolation trench and the source area, wherein the isolation trench is filled with the conductive material up to the first vertical level.

According to aspect, the first electrode includes a floating potential. The second electrode may be connected to a predetermined potential. The second electrode may form a common electrode for all first memory cells.

In a preferred aspect of the invention, a recess is formed in the first surface between the drain area and the source area, wherein the gate dielectric layer and the gate electrode are at least partially arranged in the recess. Thus, the channel extends deeper into the semiconductor body than the source and the drain area. Charges stored at large distance to the source and drain areas are still influencing the threshold value. Additionally, the curved channel is more sensitive to injected charges.

Therefore, a smaller amount of charges is sufficient for significant shift of the threshold value. A vertical extension of the recess may be larger than a vertical extension of the drain area and the source area.

According to another aspect, the source line forms a spacer in parallel to the gate electrode. As generally known, an isolating spacer is provided to the sidewalls of the gate stack for isolation purposes. Adjacent to this isolation spacer, the source line is formed as a further spacer made of a conductive material. The area consumption of such a source line is very low.

According to still another aspect of the invention, the transistor body comprises a first region and a second region. The second region is arranged near the first surface and the first region is arranged in a bulk area of the transistor body under and adjacent to the second region, wherein a doping concentration of dopants of the first conductivity type is higher in the first region than in the second region. It can be demonstrated that a leakage of the charges increases with increasing gradients at the source/drain junctions with the semiconductor body. By simply reducing the concentration, a gradient and, therefore, the leakage current of the charges is reduced.

According to another aspect of the present invention, the semiconductor body is isolated to an underlying semiconductor substrate via a dielectric barrier, or an underlying semiconductor substrate is doped with a second dopant having a conductivity type opposite to the conductivity type of the first dopant for forming a depletion area at a boundary of the semiconductor body in contact with the semiconductor substrate.

According to still another aspect, the transistor body comprises a third region, the third region is arranged adjacent to or near said semiconductor substrate and also vertical border of the transistor body wherein a doping concentration of a dopant of the first conductivity type is higher in the third region than in a bulk area of the transistor body.

According to a further preferred embodiment, an emitter area of the first conductivity type is arranged on top on the drain area and especially is embedded in said drain area adjacent to the first surface. A bipolar transistor is formed by the emitter area, the drain area and the transistor body. A small current flows from the emitter area through the drain area to the gate dielectric when respective voltages are applied to the emitter area and the gate electrode. According to the principle of a bipolar transistor a larger current may then flow from the emitter area to the transistor body. This current provides a large amount of charges filling the capacitor structures.

According to another embodiment, at least one bit line, at least one source line and at least one word line are provided. The gate electrode is connected to the word line, the drain area is connected to the bit line and the source area is connected to the source line common to a plurality of the memory cells.

### BRIEF DESCRIPTION OF THE DRAWINGS

Exemplary embodiments of the invention are illustrated in the drawings and explained in more detail in the following description.

FIG. 1 illustrates a wiring scheme of an embodiment of the present invention.

FIG. 2 illustrates a top view of an embodiment of the present invention.

FIG. 3-6 illustrate cross-sections of four embodiment of the present invention.

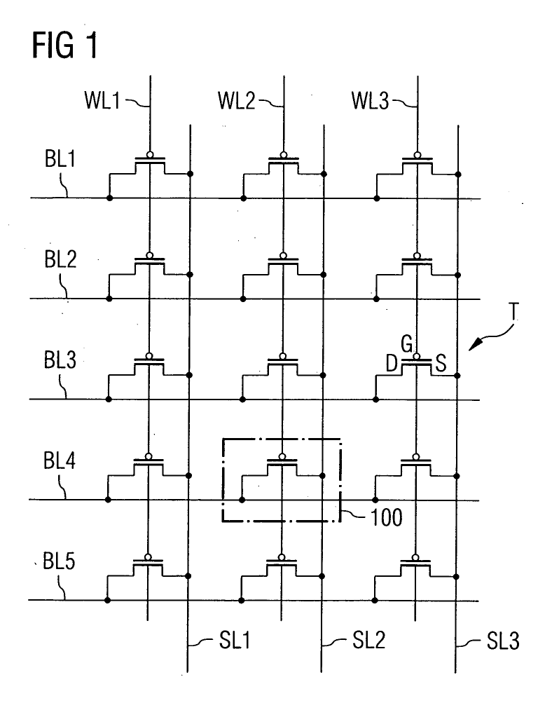

In the FIGS. 1-6, identical reference numerals denote identical or functionally equivalent parts.

### DETAILED DESCRIPTION OF THE INVENTION

FIG. 1 illustrates a wiring scheme of most embodiments of the present invention. Each memory cell 100 comprises a transistor T having a gate G connected to a word line WL1, WL2, . . . (WL), a drain D connected to a bit line BL1, BL2, . . . (BL) and a source S connected to a source line SL1, SL2, . . . (SL).

It is common to name drain and source according to the direction of a current flow. However, to keep the description of the present invention simple, the side connected to the bit line will be hereinafter always called drain and the side connected to the source line will be called source. It is understood that the nomination is arbitrary and source and drain may be interchanged. The memory cells 100 are arranged in a matrix wherein each column is addressed by a respective word line WL, and memory cells 100 along a line of the matrix are addressed by a single bit line BL. Source lines may also connect memory cells 100 columnwise or linewise at their respective source. It should be noted that source S of a memory cell is connected to a common potential shared by a plurality of memory cells and provided by a source line SL. In a RAM device, sources of different memory cells are not interconnected but only connected to its respective capacitor.

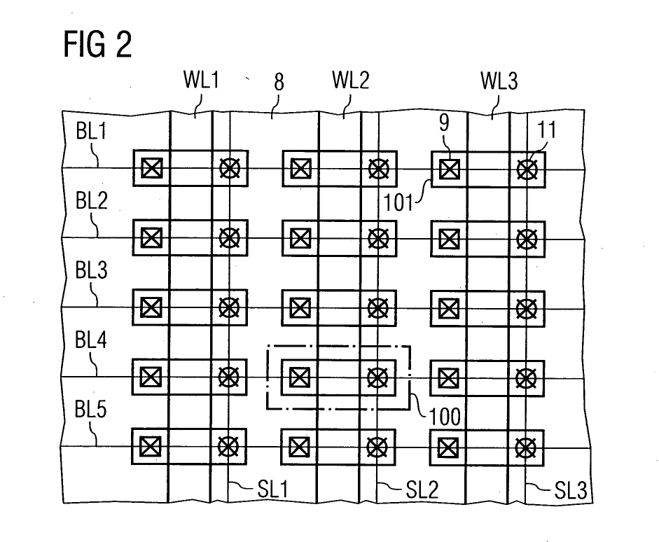

FIG. 2 illustrates a top view of an embodiment of the present semiconductor memory device. A plurality of memory cells are arranged in lines and columns. Each memory cell 100 comprises one transistor 101 having drain connected to bit lines BL via a bit line contact 9 and source connected to source lines SL. The word lines are in contact with gates of the transistors 101. The geometric arrangement of crossing word lines WL and bit lines BL is similar or identical to arrangements according to the present state of art in semiconductor memory devices. The source lines SL may be arranged in parallel to the word lines WL. It is as well possible to arrange the source lines in parallel to the bit lines BL.

Transistors of different memory cells 100 are isolated from each other by isolation trenches 8 provided between the transistors. Advantageously, the isolation trenches 8 are adjacent to at least one side of the active areas of the transistors, preferably to all sides of the active areas, in order to minimize the lateral space consumption of the memory device.

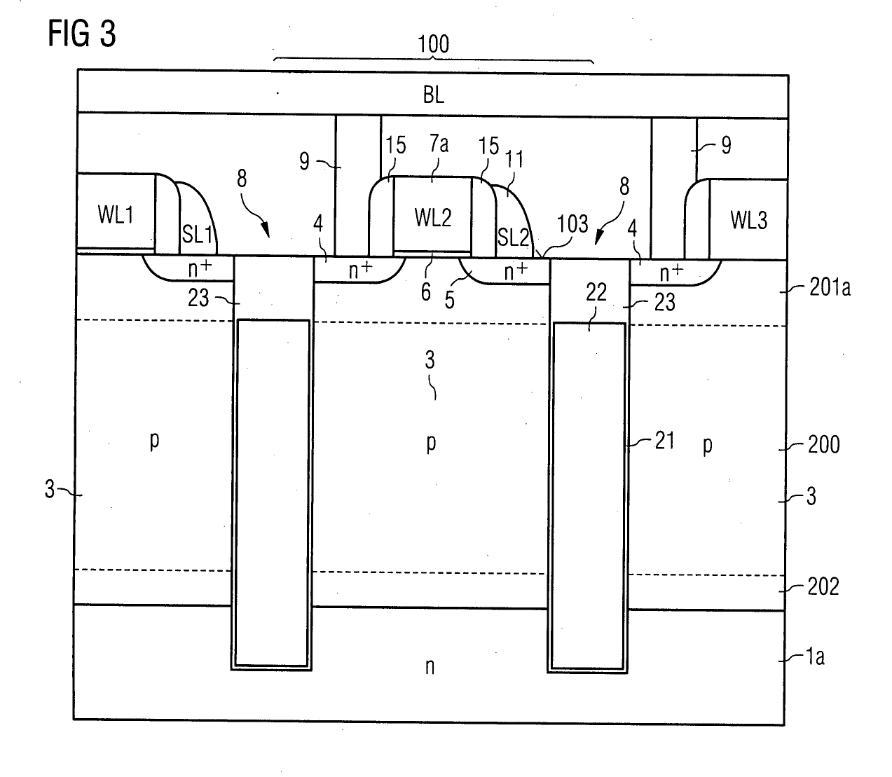

FIG. 3 illustrates a cross-section through a first embodiment of a semiconductor memory device. At a first surface of a transistor body 3, a drain area 4 and a source area 5 are arranged. The transistor body 3 comprises a semiconductor material doped with a dopant of a first conductivity type, for example a p-type. The source and drain areas are doped with a dopant of a second different conductivity type, in the present example with an n-type dopant. On the first surface 103, a gate dielectric layer 6 is at least arranged between the source and the drain area and may extend in one embodiment over the drain area 4. A gate electrode 7a is arranged on top of the gate dielectric layer 6. The gate electrode 7a may be formed by a word line WL or is connected to the word line WL. Thus, a field effect transistor (FET) is provided formed by the source area 4, a gate structure comprising the gate dielectric layer 6 and the gate electrode 7a, and the source area 5.

The transistor body 3 is arranged on a substrate la doped with a dopant of a second conductivity type, in this example an n-type. Thus, a pn-junction isolates the transistor body 3 and the semiconductor substrate la. As described hereinabove sidewalls of the transistor body 3 and the active area are surrounded by isolation trenches 8 and thus isolated from neighboring cells 100. In consequence, the transistor body 3 is isolated and potential-free and/or has a floating potential. In the following, a working principle of a semiconductor memory device and its memory cells as described herein above should be briefly explained. In general information is represented by at least two distinguishable states of a memory cell.

A characteristic of a FET is its threshold value. The threshold value is a voltage defined as a minimal voltage applied to the gate of the FET for switching a channel from a non-conductive state to a conductive state. The threshold voltage depends on charges injected into the transistor body 3. These charges are lowering the threshold voltage by several hundred millivolts. Thus two distinguishable states can be defined as a transistor body 3 having injected charges and a transistor body 3 without injected charges. A read-out of the information may be obtained by measuring the conductivity of the channel when a predetermined voltage is applied to the gate electrode 7a. The predetermined voltage is chosen such that the FET is conductive in one state but not in the second state. An example for such a predetermined voltage is a mean value of the respective threshold voltages of the FET in the first and the second state.

For a full implementation of such a memory device it is necessary to write, to store and to delete the information as well, i.e. to inject charges into the transistor body 3, to maintain charges in the transistor body 3 and to extract these charges out of the transistor body 3.

A first writing operation uses an impact ionization effect occuring in the channel. The transistor is switched to a conductive state by applying a respective voltage to its gate electrode 7 and a current flows through the channel from drain to source. Due to the impact ionization effect minority carriers, in the present example holes, are created in the channel and injected into the transistor body.

A second writing operation uses a gate-induced drain leakage effect. A negative voltage is applied to the gate electrode 7a and a positive voltage to the drain area 4. Due to quantum-mechanical tunneling process holes are injected into the transistor body 3. Basically no current is flowing between drain and source as the transistor is switched off by the negative voltage, and thus this injection mechanism of charges is highly power efficient.

The charges may be extracted from the transistor body 3 by applying a negative potential to the source line contact 11 or the source lines SL.

An aim of this embodiment is to store an information for at least 10 ms up to several hundreds of milliseconds. Thus a minimal amount of charges (minimal charge) must be maintained in the transistor body 3 for the requested duration.

The minimal charge is defined as the charge necessary to form two distinguishable states, in other words, the minimal charge must be able to shift the threshold value by a detectable amount. The storage capacitance of the floating and/or isolated transistor body 3 is limited. Its capacitance is mainly formed by the pn-junctions of the transistor body 3 on the one hand and the semiconductor substrate la, the drain area 4 and the source area 5 on the other hand. A further contribution to the capacitance is provided by a capacitor formed by the gate stack 6,7 and the transistor body 3. In such a case already a loss of a small amount of charges erases irrevocably the information. Therefore, the capacitance is increased as described herein below.

Isolation trenches 8 are formed adjacent to the transistor body 3. Such isolation trenches 8 are provided in order to isolate neighboring memory cells 100. A common method is to fill them with a dielectric material.

In the embodiment a dielectric layer 21 is provided on sidewalls of the isolation trenches 8 and the isolation trenches 8 are at least partially filled with a conductive material 22. Thus, the transistor body 3, the dielectric layer 21, and the conductive material 22 form a capacitor unit. The capacitor unit allows to store a large amount of injected charges in the transistor body 3. Thus an excess charge over the minimal charge may be stored. Thus it takes longer until the charge falls below the minimal charge due to leakage currents.

The second electrode formed by the conductive material 22 may be a common electrode for all memory cells 100, as becomes apparent by FIG. 2. The conductive material 22 may be highly doped polysilicon. Preferably, the dielectric layer 21 is a high-k dielectric and has a thickness of only a few nanometers. Thus a high capacitance of the capacitor unit is achieved.

A capacitance of a capacitor increases with a conductivity of its electrodes. In order to achieve this high conductivity of the electrode formed by the transistor body 3, a first region 200 in the bulk or volume of the transistor body 3 is highly doped. In order to maintain the charges in the transistor body leakage currents have to be minimized. The pn-junctions of the transistor body 3 formed with the drain area 4, the source area 5 and the substrate la are identified as main leakage paths for the injected charges. It was recognized that the leakage current increases with the steepness or gradient of the dopants in the area of the pn-junctions. Therefore, an absolute dopant concentration of the dopant within the transistor body 3 is kept low in a second region 201a adjacent to the drain area 4, source area 5 and in a third region 202 adjacent to the semiconductor substrate 1a.

A further advantage of the capacitor unit is that the charges may be kept away from the leakage paths around the source and the drain areas. The conductivity material 22 may be only filled into the trenches 8 up to a level below the drain and source areas 4, 5. As pointed out herein before, a low dopant profile must be provided in these areas, thus these upper parts of the trenches 8 would not contribute significantly to the capacitance. Further, a capacitor unit close to the drain and source areas may contribute to a significantly increased leakage current of the injected charges.

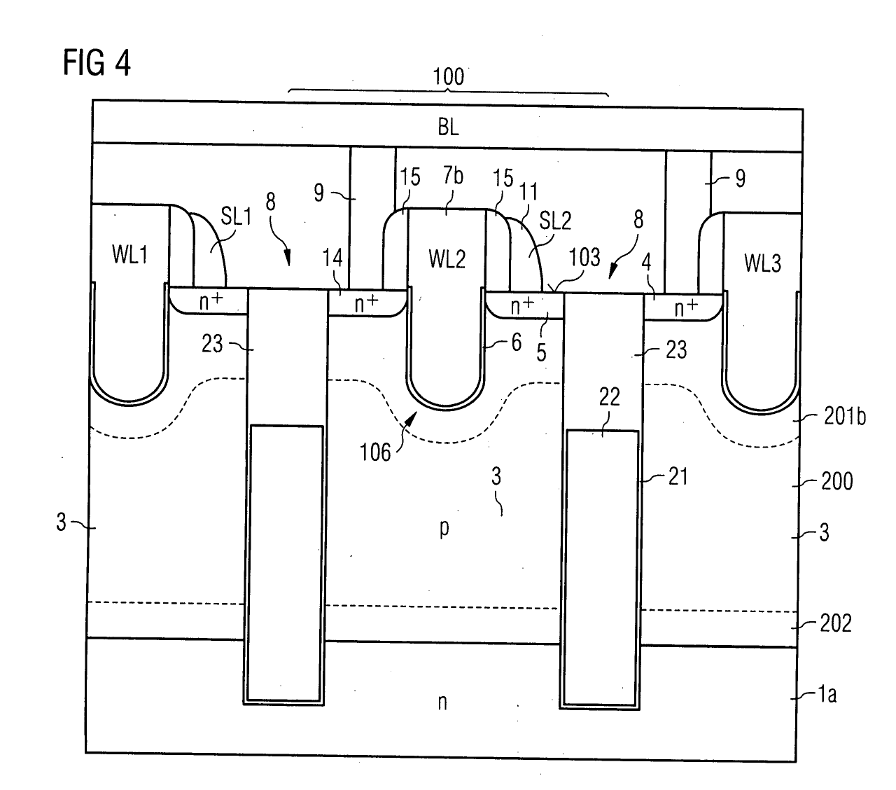

FIG. 4 illustrates a second embodiment of the semiconductor memory device. A recess 106 is formed in the first surface 103 between the drain 4 and the source area 5. The gate electrode 7b is formed in this trench. Thus the gate electrode 7b extends deep into the transistor body 3 forming a curved channel. A longer channel is provided guided along the outer surface of this recess.

A first advantage results in the fact that a longer channel reduces leakage currents from the drain area 4 to the source area 5 when the transistor is switched off. Thus the power consumption of the memory device is significantly reduced.

A further advantage results in the fact that charges which are stored far from the source and drain areas 4, 5 are still influencing the channel because it extends deep into the transistor body 3. Thus, the injected charges may be injected into areas distant to the source and drain areas. Similar to the first embodiment, a dopant concentration of a dopant is high in a first region 200 in the bulk of the transistor body 3 and is low in a second 201b close to the source area 5 and the drain area 4 and in a third area 202 close to the semiconductor substrate 1a.

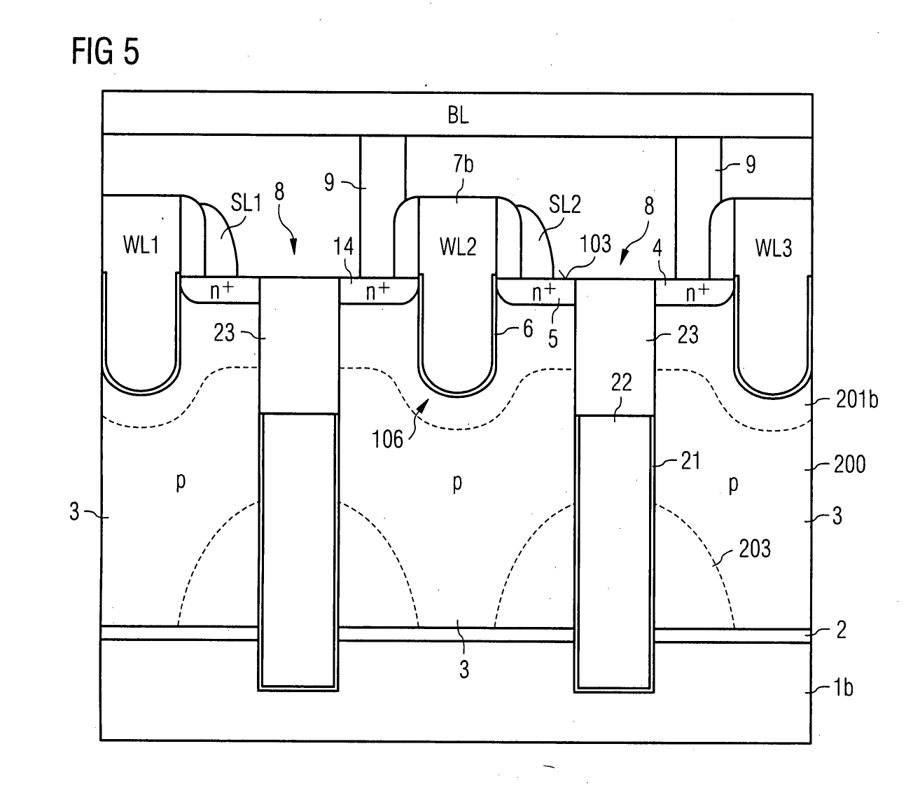

In a further preferred embodiment (FIG. 5), the semiconductor substrate 1b is isolated from the transistor body 3 by an isolation layer 2. In this case, a dopant concentration in areas 203 close to the semiconductor substrate 1b may be high. Thus, the specific capacitance of the capacitor unit in these areas is high and most of the injected charges are localized in the areas 203. Advantageously, these areas are the most distant places to the drain and source areas 4, 5. Thus, a leakage of the injected charges may be reduced to a minimum. Further, it is favorable to reduce a dopant concentration along a vertical line below the gate electrode 7b. By this way, a leakage of the stored charge into the channel during read out is reduced. Adjacent to sidewalls of the gate electrode 7b and the word line WL, spacers 15 made of an oxide or nitride may be arranged.

Additionally, a conductive spacer may form the source line SL instead of a source line contact 11. This conductive spacer is in contact with the source area 5 and formed adjacent to an isolating spacer 15.

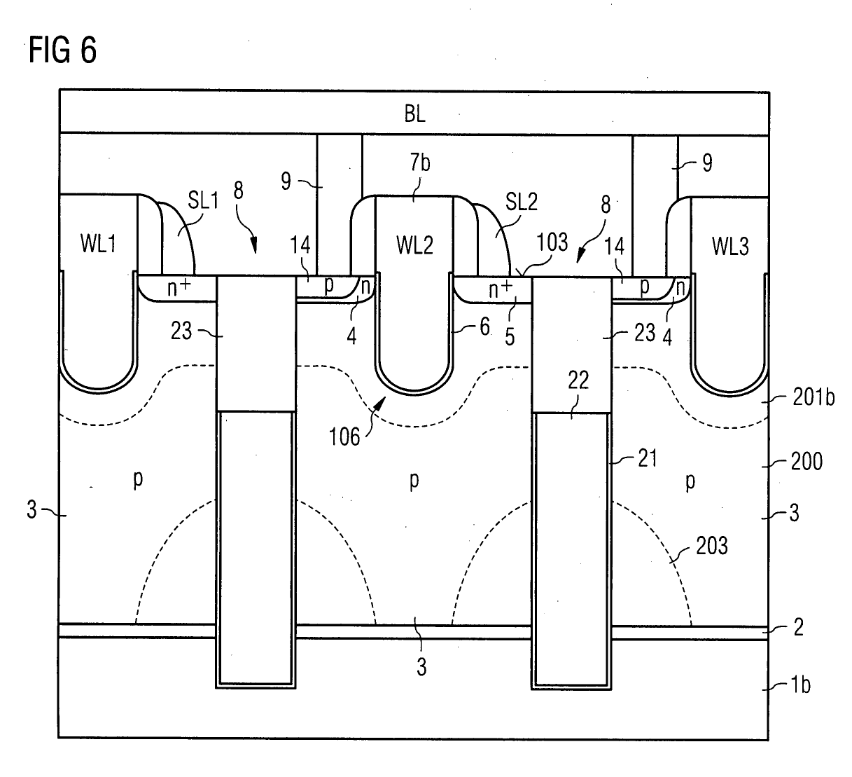

FIG. 6 illustrates a further refinement of the above embodiments. A p-doped emitter area 14 is arranged between the bit contact 9 and the drain area 4. Thus, the p-doped area 14, the n-doped drain area and the p-doped transistor body are forming a bipolar transistor. The p-doped area 14 or emitter of the bipolar transistor is not in contact with the gate electrode or the gate dielectric layer 6. A small current may flow from the emitter area 14 to parasitic capacitances in the area of the gate dielectric 6 through the drain area 4 when respective voltages are applied to the emitter area 14 and the gate electrode 7b. According to the principles of bipolar transistors an amplified current may then flow from the emitter area 14 to the transistor body 3. Then the current provides the injection of the charges. An injection of the charges by this method is far more efficient then the methods using the gate induced drain leakage and the impact ionization.

Although the present invention has been described along with preferred embodiments, the present invention is not limited thereon.

In particular, the dopants may be exchanged to dopants having the opposite conductivity type. In this case the voltages applied for the operation have to be inverted.

What is claimed is:

1. A semiconductor memory device having a plurality of memory cells, each memory cell having a respective transistor and a respective capacitor unit, the transistor comprising:
a transistor body of a first conductivity type;
a drain area and a source area each having a second conductivity type, the drain area and source area are embedded in the transistor body on a first surface of the transistor body; and
a gate structure having a gate dielectric layer and a gate electrode, the gate structure is arranged between the drain area and the source area; and
an isolation trench being arranged adjacent to the transistor body, and having a dielectric layer and a conductive material, the isolation trench is at least partially filled with the conductive material, wherein the conductive material is isolated by said dielectric layer from the transistor body, wherein
the capacitor unit is formed by the transistor body representing a first electrode and said conductive material representing the second electrode.

2. The semiconductor memory device according to claim 1, wherein a first vertical level is defined between a bottom of the isolation trench and the source area, wherein the isolation trench is filled with the conductive material up to the first vertical level.

3. The semiconductor memory device according to claim 1, wherein the first electrode contains a floating potential.

4. The semiconductor memory device according to claim 1, wherein the second electrode is connected to a predetermined potential.

5. The semiconductor memory device according to claim 1, wherein the second electrode forms a common electrode for all first memory cells.

6. The semiconductor memory device according to claim 1, wherein a recess is formed in the first surface between the drain area and the source area, wherein the gate dielectric layer and the gate electrode are at least partially arranged in the recess.

7. The semiconductor memory device according to claim 6, wherein a vertical extension of the recess is larger than a vertical extension of the drain area and/or the source area.

8. The semiconductor memory device according to claim 1, wherein a semiconductor substrate of the second conductivity type is provided, wherein the transistor body is arranged adjacent to the semiconductor substrate.

9. The semiconductor memory device according to claim 1, wherein an underlying semiconductor substrate and an isolation layer is provided, wherein the transistor body is isolated from the underlying semiconductor substrate by the isolation layer.

10. The semiconductor memory device according to claim 1, wherein the transistor body comprises a first region and a second region, wherein the second region is arranged near the first surface and the first region is arranged in a bulk area of the transistor body under and adjacent to the second region, wherein a doping concentration of dopants of the first conductivity type is higher in the first region than in the second region.

11. The semiconductor memory device according to claim 9, wherein the transistor body comprises a third region and a vertical border, the third region is arranged adjacent to both the semiconductor substrate and the vertical border of the transistor body wherein a doping concentration of a dopant of the first conductivity type is higher in the third region than in the bulk area of the transistor body.

12. The semiconductor memory device according to claim 1, wherein the source line forms a spacer, the spacer is arranged adjacent to said gate electrode and the spacer is not in contact with the gate electrode.

13. The semiconductor memory device according to claim 1, wherein an emitter area of the first conductivity type is arranged on top of the drain area.

14. The semiconductor memory device according to claim 1, wherein at least one bit line, at least one source line and at least one word line are provided, wherein the gate electrode is connected to the word line, the drain area is connected to the bit line and the source area is connected to the source line common to a plurality of the memory cells.
